(19) United States
(12) Patent Application Publication
(10) Pub. No.: US 2022/0190234 A1
(43) Pub. Date: Jun. 16, 2022

(54) MAGNETIZATION ROTATION ELEMENT, MAGNETORESISTANCE EFFECT ELEMENT, MAGNETIC MEMORY, AND METHOD OF MANUFACTURING SPIN-ORBIT TORQUE WIRING

(71) Applicant: TDK CORPORATION, Tokyo (JP)

(72) Inventors: Tomoyuki SASAKI, Tokyo (JP); Yohei SHIOKAWA, Tokyo (JP); Yugo ISHITANI, Tokyo (JP); Kosuke HAMANAKA, Tokyo (JP); Eiji KOMURA, Tokyo (JP)

(73) Assignee: TDK CORPORATION, Tokyo (JP)

(21) Appl. No.: 17/545,467

(22) Filed: Dec. 8, 2021

(30) Foreign Application Priority Data
Dec. 10, 2020 (JP) PCT/JP2020/046050
Sep. 29, 2021 (JP) 2021-158757

(51) Int. Cl. H01L 43/04; H01L 27/22; H01L 43/06; H01L 43/10; H01L 43/14

(52) U.S. Cl. CPC H01L 43/04; H01L 27/228; H01L 43/14; H01L 43/10; H01L 43/06

(57) ABSTRACT

The magnetization rotation element includes: a spin-orbit torque wiring; and a first ferromagnetic layer which is stacked on the spin-orbit torque wiring, wherein the spin-orbit torque wiring includes a plurality of wiring layers, and wherein, in a cross section orthogonal to a length direction of the spin-orbit torque wiring, a product between a cross-sectional area and a resistivity of each of the wiring layers is larger in the wiring layer closer to the first ferromagnetic layer.

### BACKGROUND OF THE INVENTION

### Field of the Invention

The present invention relates to a magnetization rotation element, a magnetoresistance effect element, a magnetic memory, and a method of manufacturing a spin-orbit torque wiring. Priority is claimed on PCT Patent Application No. PCT/JP2020/046050, filed Dec. 10, 2020, and Japanese Patent Application No. 2021-158757, filed Sep. 29, 2021, the content of which is incorporated herein by reference.

### Description of Related Art

A giant magnetoresistance (GMR) element constituted by a multilayer film of a ferromagnetic layer and a nonmagnetic layer and a tunnel magnetoresistance (TMR) element using an insulating layer (a tunnel barrier layer or a barrier layer) as a nonmagnetic layer are known as a magnetoresistance effect element. A magnetoresistance effect element can be applied to a magnetic sensor, a radio frequency component, a magnetic head, and a magnetic random access memory (MRAM).

An MRAM is a storage element in which magnetoresistance effect elements are integrated. An MRAM reads and writes data using a characteristic that a resistance of the magnetoresistance effect element changes when mutual magnetization directions of two ferromagnetic layers with the nonmagnetic layer interposed therebetween in the magnetoresistance effect element change. The magnetization directions of the ferromagnetic layers are controlled using, for example, a magnetic field generated by a current. Further, for example, the magnetization directions of the ferromagnetic layers are controlled using a spin transfer torque (STT) generated by allowing a current to flow in a stacking direction of the magnetoresistance effect elements.

In a case in which the magnetization directions of the ferromagnetic layers are rewritten using the STT, the current is allowed to flow in the stacking direction of the magnetoresistance effect elements. A write current causes deterioration of characteristics of the magnetoresistance effect element.

In recent years, attention has been focused on a method in which a current does not have to be allowed to flow in the stacking direction of the magnetoresistance effect elements during writing (for example, Patent Document 1). One such method is a writing method using a spin-orbit torque (SOT). An SOT is induced by a spin current generated by a spin-orbit interaction or a Rashba effect at an interface between different materials. A current for inducing an SOT in the magnetoresistance effect element flows in a direction intersecting the stacking direction of the magnetoresistance effect elements. That is, it is not necessary to allow a current to flow in the stacking direction of the magnetoresistance effect element, and it is expected that the life span of the magnetoresistance effect element will be extended.

### Patent Documents

[Patent Document 1] Japanese Unexamined Patent Application, First Publication No. 2017-216286

### SUMMARY OF THE INVENTION

The magnetic memory has a plurality of integrated magnetoresistance effect elements. As the amount of the current applied to each magnetoresistance effect element increases, the power consumption of the magnetic memory increases. It is required to reduce the amount of the current applied to each magnetoresistance effect element and suppress the power consumption of the magnetic memory.

The present invention has been made in view of the above circumstances, and an object of the present invention is to provide a magnetization rotation element, a magnetoresistance effect element, a magnetic memory, and a method of manufacturing a wiring for operating with a small current.

The present invention provides the following means for solving the above problems.
(1) A magnetization rotation element according to a first aspect includes: a spin-orbit torque wiring; and a first ferromagnetic layer which is stacked on the spin-orbit torque wiring, wherein the spin-orbit torque wiring includes a plurality of wiring layers, and wherein, in a cross section orthogonal to a length direction of the spin-orbit torque wiring, a product between a cross-sectional area and a resistivity of each of the wiring layers is larger in the wiring layer closer to the first ferromagnetic layer.
(2) In the magnetization rotation element according to the above aspect, the first wiring layer closest to the first ferromagnetic layer among the plurality of wiring layers may contain a compound having a pyrochlore structure.
(3) In the magnetization rotation element according to the above aspect, the compound may be an oxide.
(4) In the magnetization rotation element according to the above aspect, the oxide may be represented by a composition formula of R₂Ir₂O₇ in a stoichiometric composition, and R in the composition formula may be at least one element selected from the group consisting of Pr, Nd, Sm, Eu, Gd, Tb, Dy, and Ho.
(5) In the magnetization rotation element according to the above aspect, R in the composition formula may include a first element, and the first element may be at least one of Pr and Nd.
(6) In the magnetization rotation element according to the above aspect, R in the composition formula may include a first element and a second element, the first element may be at least one of Pr and Nd, and the second element may be at least one element selected from the group consisting of Sm, Eu, Gd, Tb, Dy, and Ho.
(7) In the magnetization rotation element according to the above aspect, a compositional proportion of the second element may be smaller than a compositional proportion of the first element.
(8) In the magnetization rotation element according to the above aspect, the oxide may be oxygen-deficient.
(9) In the magnetization rotation element according to the above aspect, the spin-orbit torque wiring may have an electrical resistivity of 1 mΩ·cm or more.
(10) In the magnetization rotation element according to the above aspect, the spin-orbit torque wiring may have an electrical resistivity of 10 mΩ·cm or less.
(11) In the magnetization rotation element according to the above aspect, any one of the plurality of wiring layers may contain a heavy metal having an atomic number larger than that of yttrium.
(12) In the magnetization rotation element according to the above aspect, any one of the plurality of wiring layers may contain one or more elements selected from the group consisting of Ag, Au, Mg, V, Pd, Cu, Si, and Al.
(13) In the magnetization rotation element according to the above aspect, any one of the plurality of wiring layers may contain a nitride.
(14) The magnetization rotation element according to the above aspect may further include: a spacer layer provided on an opposite side of the spin-orbit torque wiring from the first ferromagnetic layer. The spacer layer may contain any one or more elements selected from the group consisting of Cr, Ti, Ta, Ni, Ru, and W.
(15) In the magnetization rotation element according to the above aspect, a film thickness of the spacer layer may be 3 nm or less.
(16) A magnetoresistance effect element according to a second aspect includes: the magnetization rotation element according to the above aspect; a nonmagnetic layer in contact with the first ferromagnetic layer of the magnetization rotation element; and a second ferromagnetic layer, wherein the nonmagnetic layer is interposed between the first ferromagnetic layer and the second ferromagnetic layer.
(17) A magnetic memory according to a third aspect includes: a plurality of the magnetoresistance effect elements according to above aspect.
(18) A method of manufacturing a spin-orbit torque wiring according to a fourth aspect includes: a first film forming step of DC sputtering a metal at the same time as or after RF sputtering of an oxide to form an oxide layer having a pyrochlore structure.
(19) In the method of manufacturing a spin-orbit torque wiring according to the above aspect, the oxide may be R₂O₃ (R is at least one element selected from the group consisting of Pr, Nd, Sm, Eu, Gd, Tb, Dy, and Ho), and the metal may be Ir.
(20) In the method of manufacturing a spin-orbit torque wiring according to the above aspect, the first film forming step may be performed in an oxygen atmosphere.

A magnetization rotation element, a magnetoresistance effect element, a magnetic memory, and a method of manufacturing a spin-orbit torque wiring according the present invention can reduce the amount of a current required for operation.

### BRIEF DESCRIPTION OF THE DRAWINGS

FIG. 1 is a circuit diagram of a magnetic memory according to a first embodiment.

FIG. 2 is a cross-sectional view of a feature portion of the magnetic memory according to the first embodiment.

FIG. 3 is a cross-sectional view of a magnetoresistance effect element according to the first embodiment.

FIG. 4 is a plan view of the magnetoresistance effect element according to the first embodiment.

FIG. 5 is a view showing a crystal structure of a pyrochlore structure.

FIG. 6 is a cross-sectional view of a magnetoresistance effect element according to a first modification example.

FIG. 7 is a cross-sectional view of a magnetoresistance effect element according to a second modification example.

FIG. 8 is a cross-sectional view of a magnetoresistance effect element according to a third modification example.

FIG. 9 is a cross-sectional view of a magnetoresistance effect element according to a fourth modification example.

FIG. 10 is a cross-sectional view of a magnetization rotation element according to a second embodiment.

FIG. 11 is a cross-sectional view of a magnetoresistance effect element according to a third embodiment.

FIG. 12 is another cross-sectional view of the magnetoresistance effect element according to the third embodiment.

FIG. 13 is a cross-sectional view of a magnetoresistance effect element according to a fifth modification example.

FIG. 14 is a cross-sectional view of a magnetoresistance effect element according to a sixth modification example.

### DETAILED DESCRIPTION OF THE INVENTION

Hereinafter, the present embodiment will be described in detail with appropriate reference to the drawings. In the drawings used in the following description, a feature portion may be enlarged for convenience to make a feature easy to understand, and dimensional ratios of each constituent element and the like may be different from the actual ones. Materials, dimensions, and the like exemplified in the following description are examples, and the present invention is not limited thereto and can be appropriately modified and carried out within the scope in which the effects of the present invention are exhibited.

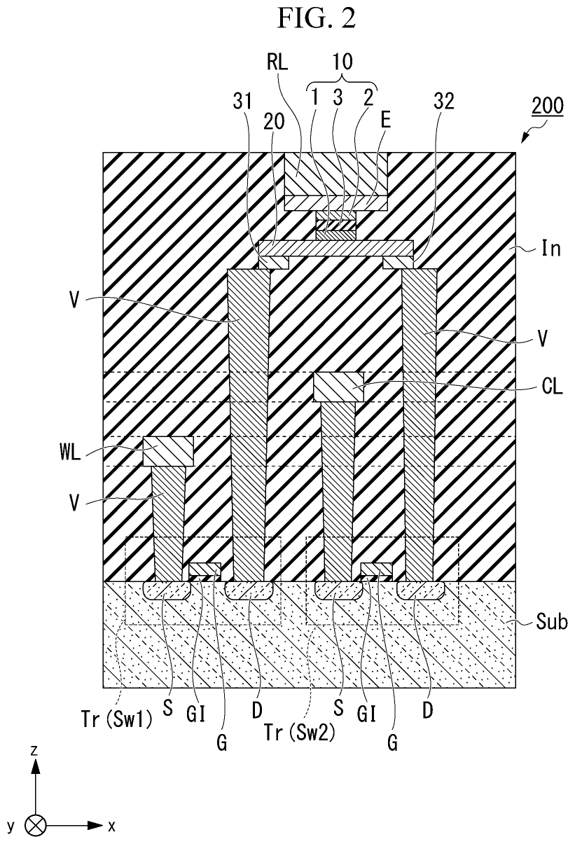

First, directions will be defined. One direction of one surface of a substrate Sub (see FIG. 2) that will be described later is defined as an x direction, and a direction orthogonal to the x direction is defined as a y direction. The x direction is, for example, a direction from a first conductive layer 31 to a second conductive layer 32. A z direction is a direction orthogonal to the x direction and the y direction. The z direction is an example of a stacking direction in which each layer is stacked. Hereinafter, a +z direction may be expressed as an “upward direction” and a −z direction may be expressed as a “downward direction.” The upward and downward directions do not always coincide with the direction in which gravity acts.

In this description, the term “extending in the x direction” means that, for example, the length in the x direction is larger than the smallest length among the lengths in the x direction, the y direction, and the z direction. The same applies to cases of extending in other directions. Further, in this description, the term “connection” is not limited to a case of being physically connected. For example, not only a case in which two layers are physically in contact with each other, but also a case in which the two layers are connected with another layer interposed therebetween is included in the “connection.”

### First Embodiment

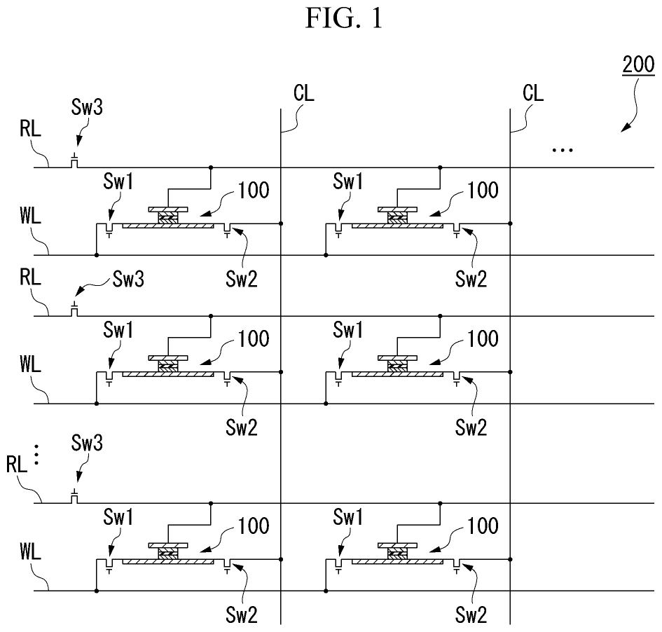

FIG. 1 is a configuration view of a magnetic memory 200 according to a first embodiment. The magnetic memory 200 includes a plurality of magnetoresistance effect elements 100, a plurality of write wirings WL, and a plurality of common wirings CL, a plurality of read wirings RL, a plurality of first switching elements Sw1, a plurality of second switching elements Sw2, and a plurality of third switching elements Sw3. The magnetic memory 200 is, for example, a magnetic array in which magnetoresistance effect elements 100 are arranged in an array shape.

Each of the write wirings WL electrically connects a power supply to one or more magnetoresistance effect elements 100. Each of the common wirings CL is a wiring used both when writing data and when reading data. Each of the common wirings CL electrically connects a reference potential to one or more magnetoresistance effect elements 100. The reference potential is, for example, a ground. Each of the common wirings CL may be provided in one of the plurality of magnetoresistance effect elements 100 or may be provided over the plurality of magnetoresistance effect elements 100. Each of the read wirings RL electrically connects a power supply to one or more magnetoresistance effect elements 100. The power supply is connected to the magnetic memory 200 during use.

Each of the magnetoresistance effect element 100 is connected to the first switching element Sw1, the second switching element Sw2, and the third switching element Sw3. The first switching element Sw1 is connected between the magnetoresistance effect element 100 and the write wiring WL. The second switching element Sw2 is connected between the magnetoresistance effect element 100 and the common wiring CL. The third switching element Sw3 is connected to the read wiring RL provided over the plurality of magnetoresistance effect elements 100.

When a predetermined first switching element Sw1 and a predetermined second switching element Sw2 are turned on, a write current flows between the write wiring WL and the common wiring CL which are connected to a predetermined magnetoresistance effect element 100. When a write current flows, data is written to the predetermined magnetoresistance effect element 100. When a predetermined second switching element Sw2 and a predetermined third switching element Sw3 are turned on, a read current flows between the common wiring CL and the read wiring RL which are connected to a predetermined magnetoresistance effect element 100. When a read current flows, data is read from the predetermined magnetoresistance effect element 100.

Each of the first switching element Sw1, the second switching element Sw2, and the third switching element Sw3 is an element that controls the flow of the current. Each of the first switching element Sw1, the second switching element Sw2, and the third switching element Sw3 is, for example, a transistor, an element using a phase change of a crystal layer such as an ovonic threshold switch (OTS), an element using a change in band structure such as a metal insulator transition (MIT) switch, an element using a breakdown voltage such as a Zener diode and an avalanche diode, and an element of which conductivity changes as an atomic position changes.

In the magnetic memory 200 shown in FIG. 1, the magnetoresistance effect elements 100 connected to the same wiring share the third switching element Sw3. The third switching element Sw3 may be provided for each magnetoresistance effect element 100. Further, the third switching element Sw3 may be provided for each magnetoresistance effect element 100, and the first switching element Sw1 or the second switching element Sw2 may be shared by the magnetoresistance effect elements 100 connected to the same wiring.

FIG. 2 is a cross-sectional view of a feature portion of the magnetic memory 200 according to the first embodiment. FIG. 2 is a cross section of the magnetoresistance effect element 100 along an xz plane passing through the center of the width of a spin-orbit torque wiring 20 that will be described later in the y direction.

Each of the first switching element Sw1 and the second switching element Sw2 shown in FIG. 2 is a transistor Tr. The third switching element Sw3 is electrically connected to the read wiring RL and is located at, for example, a position shifted in the y direction in of FIG. 2. The transistor Tr is, for example, a field effect transistor and has a gate electrode G, a gate insulating film GI, and a source S and a drain D which are formed on the substrate Sub. The source S and the drain D are predetermined according to a flow direction of the current, and they are in the same region. A positional relationship between the source S and the drain D may be reversed. The substrate Sub is, for example, a semiconductor substrate.

The transistor Tr and the magnetoresistance effect element 100 are electrically connected to each other via a via wiring V, a first conductive layer 31, and a second conductive layer 32. Further, the transistor Tr and the write wiring WL or the transistor Tr and the common wiring CL are connected to each other through the via wiring V. The via wiring V extends, for example, in the z direction. The read wiring RL is connected to a stacked body 10 via an electrode E. The via wiring V, the electrode E, the first conductive layer 31, and the second conductive layer 32 each contain a material having conductivity.

The periphery of the magnetoresistance effect element 100 and the transistor Tr is covered with an insulating layer in. The insulating layer In is an insulating layer that insulates between the wirings of multilayer wirings or between the elements. The insulating layer In is, for example, silicon oxide (SiOₓ), silicon nitride (SiNₓ), silicon carbide (SiC), chromium nitride, silicon carbonitride (SiCN), silicon oxynitride (SiON), aluminum oxide (Al₂O₃), zirconium oxide (ZrOₓ), magnesium oxide (MgO), aluminum nitride (AlN), or the like.

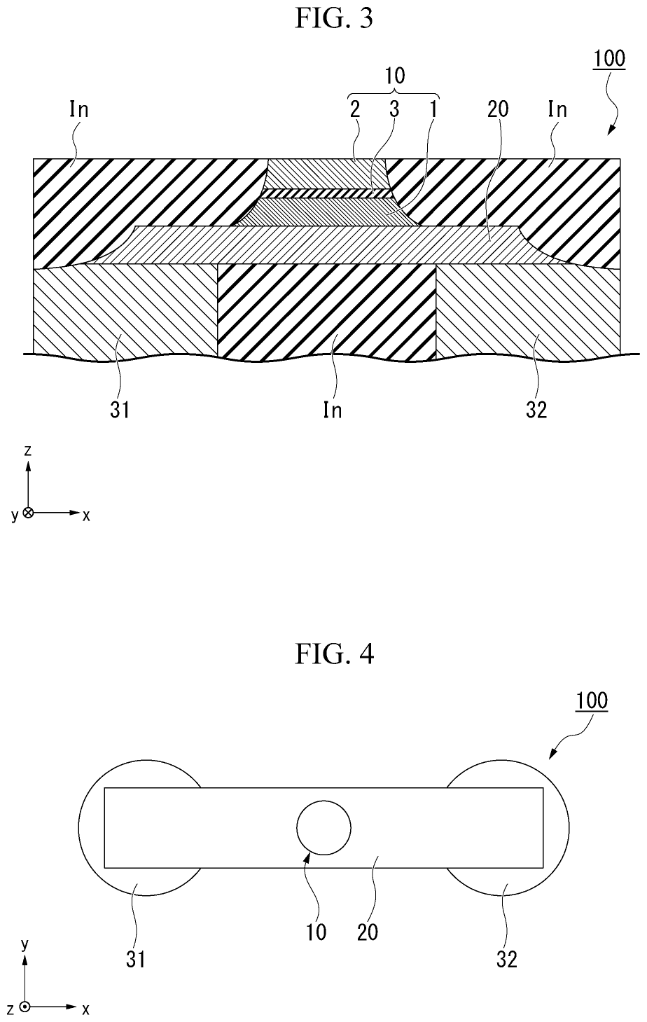

FIG. 3 is a cross-sectional view of the magnetoresistance effect element 100. FIG. 3 is a cross section of the magnetoresistance effect element 100 along an xz plane passing through the center of the width of the spin-orbit torque wiring 20 in the y direction. FIG. 4 is a plan view of the magnetoresistance effect element 100 in the z direction.

The magnetoresistance effect element 100 includes, for example, the stacked body 10, the spin-orbit torque wiring 20, the first conductive layer 31, and the second conductive layer 32. The stacked body 10 is stacked on the spin-orbit torque wiring 20. Another layer may be provided between the stacked body 10 and the spin-orbit torque wiring 20. The first conductive layer 31 and the second conductive layer 32 are connected to the spin-orbit torque wiring 20. Another layer may be provided between each of the first conductive layer 31 and the second conductive layer 32 and the spin-orbit torque wiring 20. The first conductive layer 31 and the second conductive layer 32 are located at positions between which the stacked body 10 is interposed in the z direction.

The resistance value of the stacked body 10 in the z direction changes when spins are injected from the spin-orbit torque wiring 20 into the stacked body 10. The magnetoresistance effect element 100 is a magnetic element using a spin-orbit torque (SOT) and may be referred to as a spin-orbit torque magnetoresistance effect element, a spin injection magnetoresistance effect element, or a spin current magnetoresistance effect element.

The stacked body 10 is interposed between the spin-orbit torque wiring 20 and the electrode E (see FIG. 2) in the z direction. The stacked body 10 is a columnar body. The plan view shape of the stacked body 10 in the z direction is, for example, a circle, an ellipse, or a quadrilateral. A lateral side surface of the stacked body 10 is inclined with respect to the z direction, for example.

The stacked body 10 has, for example, a first ferromagnetic layer 1, a second ferromagnetic layer 2, and a nonmagnetic layer 3. The first ferromagnetic layer 1 is in contact with the spin-orbit torque wiring 20 and is stacked on the spin-orbit torque wiring 20, for example. The spins are injected into the first ferromagnetic layer 1 from the spin-orbit torque wiring 20. In the magnetization of the first ferromagnetic layer 1, the first ferromagnetic layer 1 receives a spin-orbit torque (SOT) due to the injected spins, and an orientation direction thereof changes. The nonmagnetic layer 3 is interposed between the first ferromagnetic layer 1 and the second ferromagnetic layer 2 in the z direction.

The first ferromagnetic layer 1 and the second ferromagnetic layer 2 each have magnetization. The magnetization of the second ferromagnetic layer 2 is less likely to change in the orientation direction than the magnetization of the first ferromagnetic layer 1 when a predetermined external force is applied. The first ferromagnetic layer 1 may be referred to as a magnetization free layer, and the second ferromagnetic layer 2 may be referred to as a magnetization fixed layer or a magnetization reference layer. The stacked body 10 shown in FIG. 3 has a magnetization fixed layer on a side away from the substrate Sub and is called a top pin structure. The resistance value of the stacked body 10 changes according to a difference in relative angle of magnetization between the first ferromagnetic layer 1 and the second ferromagnetic layer 2 with the nonmagnetic layer 3 interposed therebetween.

The first ferromagnetic layer 1 and the second ferromagnetic layer 2 each contain a ferromagnetic material. The ferromagnetic material is, for example, a metal selected from the group consisting of Cr, Mn, Co, Fe, and Ni, an alloy containing one or more of these metals, an alloy containing these metals and at least one or more elements of B, C, and N, or the like. The ferromagnetic material is, for example, a Co—Fe alloy, a Co—Fe—B alloy, a Ni—Fe alloy, a Co—Ho alloy, a Sm—Fe alloy, an Fe—Pt alloy, a Co—Pt alloy, or a Co—Cr—Pt alloy.

The first ferromagnetic layer 1 and the second ferromagnetic layer 2 may each contain a Heusler alloy. A Heusler alloy contains an intermetallic compound with an XYZ or X2YZ chemical composition. X is a transition metal element or noble metal element from the Co, Fe, Ni, or Cu group in the periodic table, Y is a transition metal element from the Mn, V, Cr, or Ti group in the periodic table or the same type of element as for X, and Z is a typical element from Groups 111 to V in the periodic table. The Heusler alloy is, for example, Co₂FeSi, Co₂FeGe, Co₂FeGa, Co₂MnSi, Co₂Mn₁₋ₐFeₐAl_{1-b}, Co₂FeGe_{1-c}Ga_{c}, or the like. The Heusler alloy has a high spin polarization.

The nonmagnetic layer 3 contains a nonmagnetic material. In a case in which the nonmagnetic layer 3 is an insulator (in a case in which the nonmagnetic layer 3 is a tunnel barrier layer), it is possible to use, for example, Al₂O₃, SiO₂, MgO, MgAl₂O₄, or the like as a material of the nonmagnetic layer 3. In addition to these, it is possible to also use a material in which part of Al, Si, or Mg thereof is replaced with Zn, Be, or the like as the material of the nonmagnetic layer 3. Among these, MgO and MgAl₂O₄ are materials that can realize a coherent tunneling, and thus it is possible to inject the spins efficiently. In a case in which the nonmagnetic layer 3 is a metal, it is possible to use Cu, Au, Ag or the like as the material of the nonmagnetic layer 3. Further, in a case in which the nonmagnetic layer 3 is a semiconductor, it is possible to use Si, Ge, CuInSe₂, CuGaSe₂, Cu(In, Ga)Se₂, or the like as the material of the nonmagnetic layer 3.

The stacked body 10 may have a layer other than the first ferromagnetic layer 1, the second ferromagnetic layer 2, and the nonmagnetic layer 3. For example, an underlayer may be provided between the spin-orbit torque wiring 20 and the first ferromagnetic layer 1. The underlayer enhances the crystallinity of each layer constituting the stacked body 10. Further, for example, a cap layer may be provided on the uppermost surface of the stacked body 10.

Further, the stacked body 10 may have a ferromagnetic layer on a surface of the second ferromagnetic layer 2 opposite to the nonmagnetic layer 3 via a spacer layer. The second ferromagnetic layer 2, the spacer layer, and the ferromagnetic layer form a synthetic antiferromagnetic structure (an SAF structure). The synthetic antiferromagnetic structure is constituted by two magnetic layers with a nonmagnetic layer interposed therebetween. Antiferromagnetic coupling between the second ferromagnetic layer 2 and the ferromagnetic layer increases a coercivity of the second ferromagnetic layer 2 as compared with a case without the ferromagnetic layer. The ferromagnetic layer is, for example, IrMn, PtMn, or the like. The spacer layer contains, for example, at least one selected from the group consisting of Ru, Ir, and Rh.

When seen in the z direction, for example, the length of the spin-orbit torque wiring 20 in the x direction is longer than that in the y direction and extends in the x direction. The write current flows in the x direction of the spin-orbit torque wiring 20. The first ferromagnetic layer 1 is interposed between at least part of the spin-orbit torque wiring 20 and the nonmagnetic layer 3 in the z direction.

The spin-orbit torque wiring 20 generates a spin current due to a spin Hall effect when a current I flows and injects spins into the first ferromagnetic layer 1. The spin-orbit torque wiring 20 provides, for example, a spin-orbit torque (SOT) sufficient to reverse the magnetization of the first ferromagnetic layer 1 for the magnetization of the first ferromagnetic layer 1. The spin Hall effect is a phenomenon in which a spin current is induced in a direction orthogonal to a direction in which a current flows based on spin-orbit interaction when the current flows. The spin Hall effect is the same as a normal Hall effect in that a movement (traveling) direction of moving (traveling) charges (electrons) is bent. In the normal Hall effect, the movement direction of charged particles moving in a magnetic field is bent with a Lorentz force. On the other hand, in the spin Hall effect, even if a magnetic field is absent, the movement direction of the spins is bent only due to the movement of electrons (only due to the flowing current).

For example, when a current flows through the spin-orbit torque wiring 20, a first spin oriented in one direction and a second spin oriented in a direction opposite to the first spin are each bent in a direction orthogonal to a direction in which the current 1 flows due to the spin Hall effect. For example, the first spin oriented in a −y direction is bent in the +z direction, and the second spin oriented in a +y direction is bent in the −z direction.

In a nonmagnetic material (a material that is not a ferromagnetic material), the number of electrons in the first spin and the number of electrons in the second spin which are generated by the spin Hall effect are equal to each other. That is, the number of electrons in the first spin in the +z direction is equal to the number of electrons in the second spin in the −z direction. The first spin and the second spin flow in a direction of eliminating uneven distribution of the spins. In the movement of the first spin and the second spin in the z direction, the flows of the charges cancel each other out, so that the amount of the current becomes zero. A spin current without a current is particularly referred to as a pure spin current.

When the flow of electrons in the first spin is represented as J_{↑}, the flow of electrons in the second spin is represented as J_{↓}, and the spin current is represented as J_{S}, J_{S}=J_{↑}−J₇₅ is defined. The spin current J_{S} is generated in the z direction. The first spin is injected into the first ferromagnetic layer 1 from the spin-orbit torque wiring 20.

The spin-orbit torque wiring 20 contains a compound having a pyrochlore structure. The spin-orbit torque wiring 20 may be made of the compound having a pyrochlore structure.

The compound having a pyrochlore structure is, for example, any one of an oxide, an oxynitride, a fluoride, and a hydroxide. The compound having a pyrochlore structure is, for example, an oxide. The oxide is easy to handle. In addition, the oxide having a pyrochlore structure has a higher electrical resistivity than a metal. When a high voltage can be applied between the first conductive layer 31 and the second conductive layer 32, the efficiency of injecting spins from the spin-orbit torque wiring 20 into the first ferromagnetic layer 1 is increased.

An oxide represented by a composition formula of R₂Ir₂O₇ is an example of the oxide having a pyrochlore structure. R in the composition formula is at least one element selected from the group consisting of Pr, Nd, Sm, Eu, Gd, Tb, Dy, and Ho. Although the above composition formula is described as a stoichiometric composition, deviation from the stoichiometric composition is allowed within a range in which a crystal structure can be maintained. For example, the oxide having a pyrochlore structure may be oxygen-deficient. The conductivity of the spin-orbit torque wiring 20 can be adjusted according to the degree of oxygen deficiency.

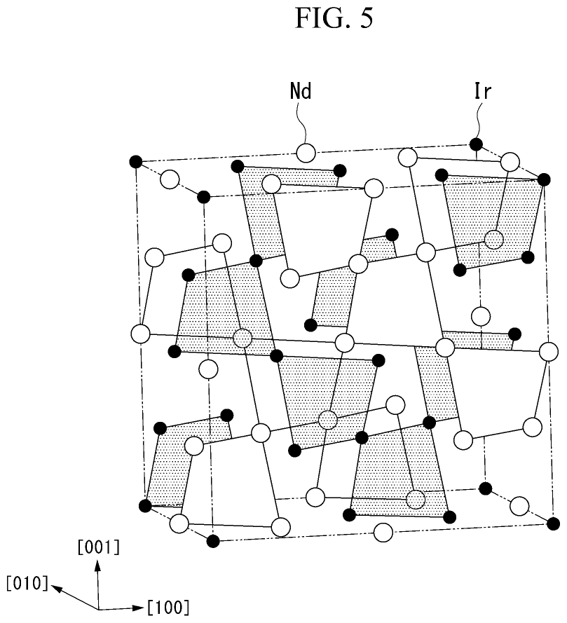

FIG. 5 is a view showing a crystal structure of a pyrochlore structure. FIG. 5 shows a crystal structure of Nd₂Ir₂O₇. In FIG. 5, oxygen is omitted. The pyrochlore structure is a structure in which two cations (a Nd ion and an Ir ion) are arranged in a plane orientation <110>. The pyrochlore structure has a structure in which R atoms form a regular tetrahedron and the regular tetrahedrons are three-dimensionally connected while sharing vertices thereof.

In the regular tetrahedron of the pyrochlore structure, magnetic frustration occurs in a case in which a magnetic interaction between the closest atoms is antiferromagnetic. The magnetic frustration disrupts magnetic balance within a substance and increases spin fluctuation. The pyrochlore structure does not have a long-range correlation between magnetic ions at room temperature and has paramagnetism or magnetic properties similar to the paramagnetism.

The spin-orbit torque wiring 20 that has the compound having a pyrochlore structure can generate a large spin current. It is considered that the magnetic frustration disturbs symmetry in the spin-orbit torque wiring 20 to cause a strong spin-orbit interaction between a conduction electron and a localized electron.

R in the composition formula may include at least one element of Pr and Nd. These elements are each referred to as a first element. The pyrochlore structure including the first element has a lower electrical resistivity than that in a case in which R in the composition formula is another element. Therefore, an operating voltage of the magnetoresistance effect element 100 can be lowered.

Further, the pyrochlore structure including the first element has a resistance value exhibiting metallic behavior with respect to temperature. The metallic behavior of the resistance value is that the resistance value is larger as the temperature is higher. In this case, as the temperature of the spin-orbit torque wiring 20 is higher, the current is less likely to flow. In other words, the amount of the spins injected into the first ferromagnetic layer 1 from the spin-orbit torque wiring 20 is smaller as the temperature is higher. Incidentally, the magnetization of the first ferromagnetic layer 1 is more likely to be reversed as the temperature is higher. If the amount of the spins injected into the first ferromagnetic layer 1 is small at a high temperature at which magnetization reversal is likely to occur, and the amount of the spins injected into the first ferromagnetic layer 1 is large at a low temperature at which magnetization reversal is less likely to occur, temperature dependence of the magnetoresistance effect element 100 as a whole is reduced.

Further, R in the composition formula may include the first element and one or more elements selected from the group consisting of Sm, Eu, Gd, Tb, Dy, and Ho. One or more elements selected from the group consisting of Sm, Eu, Gd, Tb, Dy, and Ho are each referred to as a second element.

The pyrochlore structure including the second element has a resistance value exhibiting semiconductive behavior with respect to temperature. The semiconductive behavior of the resistance value is that the resistance value is smaller as the temperature is higher.

When the compound having a pyrochlore structure has both the first element and the second element, the metallic behavior and the semiconductive behavior of the resistance value cancel out each other, and the influence of the temperature on the spin-orbit torque wiring 20 is reduced.

Further, a compositional proportion of the second element included in the pyrochlore structure is smaller than a compositional proportion of the first element, for example. In this case, the resistance value of the spin-orbit torque wiring 20 exhibits metallic behavior with respect to temperature. When the spin-orbit torque wiring 20 includes the second element, it is possible to avoid that the resistance value exhibits extremely metallic behavior. Further, in the magnetoresistance effect element 100 as a whole, the spin-orbit torque wiring 20 exhibits metallic behavior, and thus the temperature dependence is reduced.

The spin-orbit torque wiring 20 has an electrical resistivity of 1 mΩ·cm or more, for example. Further, the spin-orbit torque wiring 20 has an electrical resistivity of 10 mΩ·cm or less, for example. When the electrical resistivity of the spin-orbit torque wiring 20 is high, a high voltage can be applied to the spin-orbit torque wiring 20. When the potential of the spin-orbit torque wiring 20 becomes high, it is possible to efficiently supply the spins from the spin-orbit torque wiring 20 to the first ferromagnetic layer 1. Further, when the spin-orbit torque wiring 20 has a certain level of conductivity or more, a current path flowing along the spin-orbit torque wiring 20 can be secured, and the spin current due to the spin Hall effect can be efficiently generated.

The spin-orbit torque wiring 20 has a thickness of 4 nm or more, for example. The spin-orbit torque wiring 20 has a thickness of 20 nm or less, for example.

In a case in which the spin-orbit torque wiring 20 is made of a metal, when a film thickness of the spin-orbit torque wiring 20 is reduced, it is possible to allow a current having a current density equal to or higher than a reversal current density to flow along the spin-orbit torque wiring 20. However, it is difficult to homogeneously form the spin-orbit torque wiring 20 as the film thickness is more reduced. The reversal current density is a current density required to reverse the magnetization of the magnetoresistance effect element 100, and the magnetoresistance effect element 100 operates with reversal of the magnetization.

On the other hand, in a case in which the electrical resistivity of the spin-orbit torque wiring 20 is high, even if the spin-orbit torque wiring 20 is thick, the current density of the current flowing along the spin-orbit torque wiring 20 can be made equal to or higher than the reversal current density. When the spin-orbit torque wiring 20 is thick, it is easy to form the spin-orbit torque wiring 20 homogeneously, and variation among the plurality of magnetoresistance effect elements 100 can be reduced.

The spin-orbit torque wiring 20 may also contain a magnetic metal or a topological insulator. The topological insulator is a material in which the interior of the material is an insulator or a high resistance body and a spin-polarized metal state is generated on its surface.

Each of the first conductive layer 31 and the second conductive layer 32 is an example of a conductive layer. Each of the first conductive layer 31 and the second conductive layer 32 is made of a material having excellent conductivity. Each of the first conductive layer 31 and the second conductive layer 32 is, for example, Al, Cu, W, or Cr.

Next, a method of manufacturing the magnetoresistance effect element 100 will be described. The magnetoresistance effect element 100 is formed by a stacking step of each layer and a processing step of processing part of each layer into a predetermined shape. For the stacking of each layer, a sputtering method, a chemical vapor deposition (CVD) method, an electron beam vapor deposition method (an EB vapor deposition method), an atomic laser deposition method, or the like can be used. The processing of each layer can be performed using photolithography or the like.

First, impurities are doped at a predetermined position on the substrate Sub to form the source S and the drain D. Next, the gate insulating film GI and the gate electrode G are formed between the source S and the drain D. The source S, the drain D, the gate insulating film GI, and the gate electrode G form the transistor Tr.

Next, the insulating layer In is formed to cover the transistor Tr. Further, by forming an opening in the insulating layer In and filling the opening with a conductive material, the via wiring V, the first conductive layer 31, and the second conductive layer 32 are formed. The write wiring WL and the common wiring CL are formed by stacking the insulating layer In to a predetermined thickness, forming a groove in the insulating layer In, and filling the groove with a conductive material.

Next, an oxide layer is stacked on one surface of each of the insulating layer In, the first conductive layer 31, and the second conductive layer 32. A step of forming the oxide layer is referred to as a first film forming step. The oxide layer contains an oxide having a pyrochlore structure. In the first film forming step, DC sputtering of a metal is performed at the same time as or after RF sputtering of an oxide. The first film forming step is performed, for example, in an oxygen atmosphere. By adjusting an oxygen partial pressure, it is possible to adjust a compositional proportion of oxygen in the oxide having a pyrochlore structure.

The oxide subjected to the RF sputtering is, for example, R₂O₃ (R is at least one element selected from the group consisting of Pr, Nd, Sm, Eu, Gd, Tb, Dy, and Ho). The metal on which the DC sputtering is performed is, for example, Ir. When the target oxide and metal migrate on a surface to be filmed, an oxide layer that contains an oxide having a pyrochlore structure is obtained.

Next, the ferromagnetic layer, the nonmagnetic layer, the ferromagnetic layer, and a hard mask layer are stacked in order on the oxide layer. Next, the hard mask layer is processed into a predetermined shape. The predetermined shape is, for example, an outer shape of the spin-orbit torque wiring 20. Next, the oxide layer, the ferromagnetic layer, the nonmagnetic layer, and the ferromagnetic layer are processed into the predetermined shape at once via the hard mask layer. The oxide layer is processed into the predetermined shape to become the spin-orbit torque wiring 20.

Next, an unnecessary portion of the hard mask layer in the x direction is removed. The hard mask layer becomes an outer shape of the stacked body 10. Next, an unnecessary portion of the stacked body formed on the spin-orbit torque wiring 20 in the x direction is removed via the hard mask layer. The stacked body is processed into a predetermined shape to become the stacked body 10. The hard mask layer becomes the electrode E. Next, the periphery of the stacked body 10 and the spin-orbit torque wiring 20 is filled with the insulating layer In, and the magnetoresistance effect element 100 is obtained.

The magnetoresistance effect element 100 according to the first embodiment can efficiently generate the spin current in the spin-orbit torque wiring 20 and can efficiently inject the spins into the first ferromagnetic layer 1 from the spin-orbit torque wiring 20. Therefore, the magnetoresistance effect element 100 according to the first embodiment can reduce the amount of the write current required to reverse the magnetization of the first ferromagnetic layer 1. When the amount of the write current of each element is small, the power consumption of the entire magnetic memory 200 can be reduced.

This is because the spin-orbit torque wiring 20 has the pyrochlore structure. The magnetic frustration that occurs in the pyrochlore structure disturbs the symmetry in the spin-orbit torque wiring 20 and efficiently generates the spin current in the spin-orbit torque wiring 20. The generated spin current is efficiently injected into the first ferromagnetic layer 1 according to a potential difference between the spin-orbit torque wiring 20 and the first ferromagnetic layer 1.

Although an example of the magnetoresistance effect element 100 according to the first embodiment has been shown above, addition, omission, replacement, and other changes in configuration can be made without departing from the spirit of the present invention.

### FIRST MODIFICATION EXAMPLE

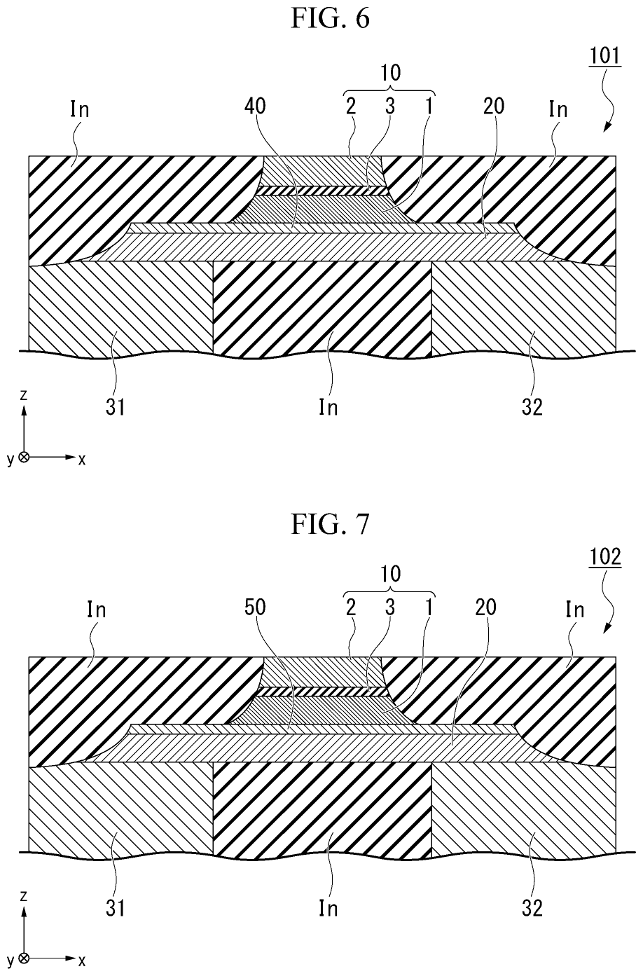

FIG. 6 is a cross-sectional view of a magnetoresistance effect element 101 according to a first modification example. FIG. 6 is an xz cross section passing through the center of the width of the spin-orbit torque wiring 20 in the y direction. In FIG. 6, the same constituent elements as those in FIG. 3 are designated by the same reference signs, and the description thereof will be omitted.

The magnetoresistance effect element 101 according to the first modification example has a first intermediate layer 40 between the spin-orbit torque wiring 20 and the first ferromagnetic layer 1. The first intermediate layer 40 is on the spin-orbit torque wiring 20, for example.

The first intermediate layer 40 contains a nonmagnetic heavy metal. The heavy metal is a metal having an atomic number (a specific gravity) equal to or larger than that of yttrium (Y). The nonmagnetic heavy metal is, for example, a nonmagnetic metal having a d-electron or an f-electron in the outermost shell and having a large atomic number equal to or larger than 39. The first intermediate layer 40 contains, for example, any one or more of Au, Bi, Hf, 1r, Mo, Pd, Pt, Rh, Ru, Ta, and W. Preferably, the main element of the first intermediate layer 40 is, for example, any one of these elements.

The first intermediate layer 40 does not have to be a completely continuous layer, and may be, for example, a continuous film having a plurality of openings or a layer including a plurality of constituent elements scattered in an island shape.

The first intermediate layer 40 has a thickness equal to or less than a spin diffusion length of a substance constituting the layer, for example. Further, the thickness of the first intermediate layer 40 is, for example, five times or less a bond radius of the element constituting the first intermediate layer 40. The bond radius is a value that is half a distance between re-neighboring atoms of the crystal of the element constituting the first intermediate layer 40. Since the first intermediate layer 40 is thin, it is possible to prevent the spins generated in the spin-orbit torque wiring 20 from diffusing before reaching the first ferromagnetic layer 1.

The first intermediate layer 40 is formed in a second film forming step. The second film forming step is performed after the first film forming step. The second film forming step is a step of forming a heavy metal layer containing a heavy metal having an atomic number larger than that of yttrium on the oxide layer formed in the first film forming step.

A gas pressure in a chamber in the second film forming step is made higher than a gas pressure in a chamber in the first film forming step, for example. That is, a degree of vacuum in the second film forming step is made lower than that in the first film forming step.

When the degree of vacuum in the second film forming step is low, a nonmagnetic heavy metal grows in grain. When the nonmagnetic heavy metal grows in grain, the first intermediate layer 40 becomes a continuous film having a plurality of openings or a layer including a plurality of constituent elements scattered in an island shape. In this case, the spin-orbit torque wiring 20 and the first ferromagnetic layer 1 are partially in direct contact with each other, and thus it is possible to further prevent the spins generated in the spin-orbit torque wiring 20 from diffusing in the first intermediate layer 40 before reaching the first ferromagnetic layer 1.

The write current flows along a wiring obtained by combining the first intermediate layer 40 and the spin-orbit torque wiring 20. The write current flowing through the wiring is divided into the write current toward the first intermediate layer 40 and the write current toward the spin-orbit torque wiring 20. By dividing part of the current, it is possible to suppress heat generation in the spin-orbit torque wiring 20 in which the current is less likely to flow. Further, the resistance of the wiring as a whole can be reduced.

In the nonmagnetic heavy metal constituting the first intennediate layer 40, the spin-orbit interaction is more strongly caused than in other metals. Therefore, the write current flowing in the first intermediate layer 40 also generates a spin current.

Further, when the first intermediate layer 40 is provided, an interface of different substances is formed between the first intermediate layer 40 and the spin-orbit torque wiring 20. In the interface of the different substances, the Rashba effect occurs and the amount of the spins injected into the first ferromagnetic layer 1 increases.

### SECOND MODIFICATION EXAMPLE

FIG. 7 is a cross-sectional view of a magnetoresistance effect element 102 according to a second modification example. FIG. 7 is an xz cross section passing through the center of the width of the spin-orbit torque wiring 20 in the y direction. In FIG. 7, the same constituent elements as those in FIG. 3 are designated by the same reference signs, and the description thereof will be omitted.

The magnetoresistance effect element 102 according to the first modification example has a second intermediate layer 50 between the spin-orbit torque wiring 20 and the first ferromagnetic layer 1. The second intermediate layer 50 is on the spin-orbit torque wiring 20, for example.

The second intermediate layer 50 contains one or more elements selected from the group consisting of Cu, Al, and Si. The second intermediate layer 50 is made of, for example, one or more elements selected from the group consisting of Cu, Al, and Si. These elements are excellent in conductivity. Therefore, the resistance of a wiring obtained by combining the second intermediate layer 50 and the spin-orbit torque wiring 20 as a whole can be reduced. In addition, these elements each have a long spin diffusion length. Therefore, the second intermediate layer 50 is less likely to diffuse the spins. The spins generated in the spin-orbit torque wiring 20 is efficiently supplied to the first ferromagnetic layer 1 even via the second intermediate layer 50.

The second intermediate layer 50 does not have to be a completely continuous layer, and may be, for example, a continuous film having a plurality of openings or a layer including a plurality of constituent elements scattered in an island shape. The second intermediate layer 50 has a thickness equal to or less than a spin diffusion length of a substance constituting the layer, for example.

The second intermediate layer 50 is formed in a third film forming step. The third film forming step is performed after the first film forming step. The third film forming step is a step of forming a layer containing one or more elements selected from the group consisting of Cu, Al, and Si on the oxide layer formed in the first film forming step.

The write current flows along a wiring obtained by combining the second intermediate layer 50 and the spin-orbit torque wiring 20. The write current flowing through the wiring is divided into the write current toward the second intermediate layer 50 and the write current toward the spin-orbit torque wiring 20. By dividing part of the current, it is possible to suppress heat generation in the spin-orbit torque wiring 20 in which the current is less likely to flow. Further, the resistance of the wiring as a whole can be reduced.

Further, when the second intermediate layer 50 is provided, an interface of different substances is formed between the second intermediate layer 50 and the spin-orbit torque wiring 20. In the interface of the different substances, the Rashba effect occurs and the amount of the spins injected into the first ferromagnetic layer 1 increases.

### THIRD MODIFICATION EXAMPLE

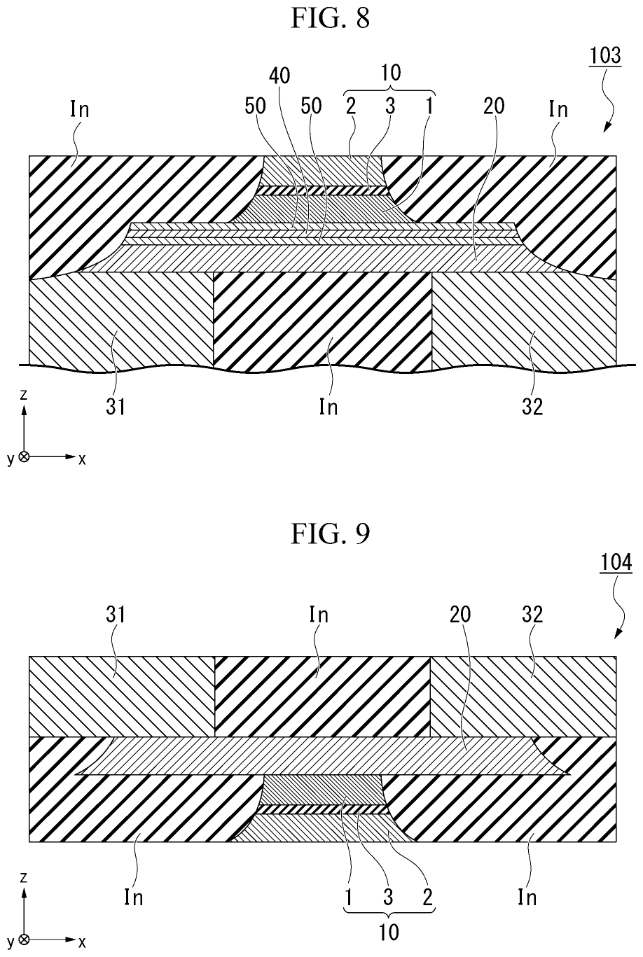

FIG. 8 is a cross-sectional view of a magnetoresistance effect element 103 according to a third modification example. FIG. 8 is an xz cross section passing through the center of the width of the spin-orbit torque wiring 20 in the y direction. In FIG. 8, the same constituent elements as those in FIG. 3 are designated by the same reference signs, and the description thereof will be omitted.

The magnetoresistance effect element 103 according to the third modification example has the first intermediate layer 40 and the second intermediate layer 50 between the spin-orbit torque wiring 20 and the first ferromagnetic layer 1. The first intermediate layer 40 and the second intermediate layer 50 each have one or more layers. The first intermediate layer 40 and the second intermediate layer 50 are stacked alternately, for example. A stacking order of the first intermediate layer 40 and the second intermediate layer 50 does not matter. In a case in which a layer in contact with the first ferromagnetic layer 1 is the first intermediate layer 40, the spins generated in the first intermediate layer 40 can be efficiently injected into the first ferromagnetic layer 1.

The first intermediate layer 40 is the same as that of the first modification example. The second intermediate layer 50 is the same as that of the second modification example. The number of stacked layers of the first intermediate layer 40 and the second intermediate layer 50 does not matter. The first intermediate layer 40 and the second intermediate layer 50 are formed by repeating the second film forming step and the third film forming step after the first film forming step. These layers are formed on the oxide layer formed in the first film forming step.

With the first intermediate layer 40 and the second intermediate layer 50, the magnetoresistance effect element 103 can reduce the resistance of the wiring as a whole. Further, since a plurality of different interfaces are present between the first ferromagnetic layer 1 and the spin-orbit torque wiring 20, the amount of the spins injected into the first ferromagnetic layer 1 can be increased due to the Rashba effect.

### FOURTH MODIFICATION EXAMPLE

FIG. 9 is a cross-sectional view of a magnetoresistance effect element 104 according to a fourth modification example. FIG. 9 is an xz cross section passing through the center of the width of the spin-orbit torque wiring 20 in the y direction. In FIG. 9, the same constituent elements as those in FIG. 3 are designated by the same reference signs, and the description thereof will be omitted.

The stacked body 10 shown in FIG. 9 has a bottom pin structure in which the magnetization fixed layer (the second ferromagnetic layer 2) is closer to the substrate Sub. When the magnetization fixed layer is on the substrate Sub side, stability in magnetization of the magnetization fixed layer increases, and an MR ratio of the magnetoresistance effect element 104 increases. The spin-orbit torque wiring 20 is on the stacked body 10, for example. The first conductive layer 31 and the second conductive layer 32 are on the spin-orbit torque wiring 20.

In the magnetoresistance effect element 104 according to the fourth modification example, only a positional relationship of the constituent elements is different from that of the magnetoresistance effect element 100 according to the first embodiment, and the same effect as the magnetoresistance effect element 100 according to the first embodiment can also be obtained.

### Second Embodiment

FIG. 10 is a cross-sectional view of a magnetization rotation element 105 according to a second embodiment. In FIG. 1, the magnetization rotation element 105 can replace the magnetoresistance effect element 100 according to the first embodiment.

In the magnetization rotation element 105, for example, light is incident on the first ferromagnetic layer 1, and the light reflected by the first ferromagnetic layer 1 is evaluated. When the magnetization orientation direction changes due to a magnetic Kerr effect, a deflection state of the reflected light changes. The magnetization rotation element 105 can be used, for example, as an optical element such as an image display device that utilizes a difference in deflection state of light.

In addition, the magnetization rotation element 105 can be used alone as an anisotropic magnetic sensor, an optical element that utilizes a magnetic Faraday effect, or the like.

The spin-orbit torque wiring 20 of the magnetization rotation element 105 has a compound having a pyrochlore structure.

In the magnetization rotation element 105 according to the second embodiment, only the nonmagnetic layer 3 and the second ferromagnetic layer 2 are removed from the magnetoresistance effect element 100, and the same effect as the magnetoresistance effect element 100 according to the first embodiment can be obtained.

### Third Embodiment

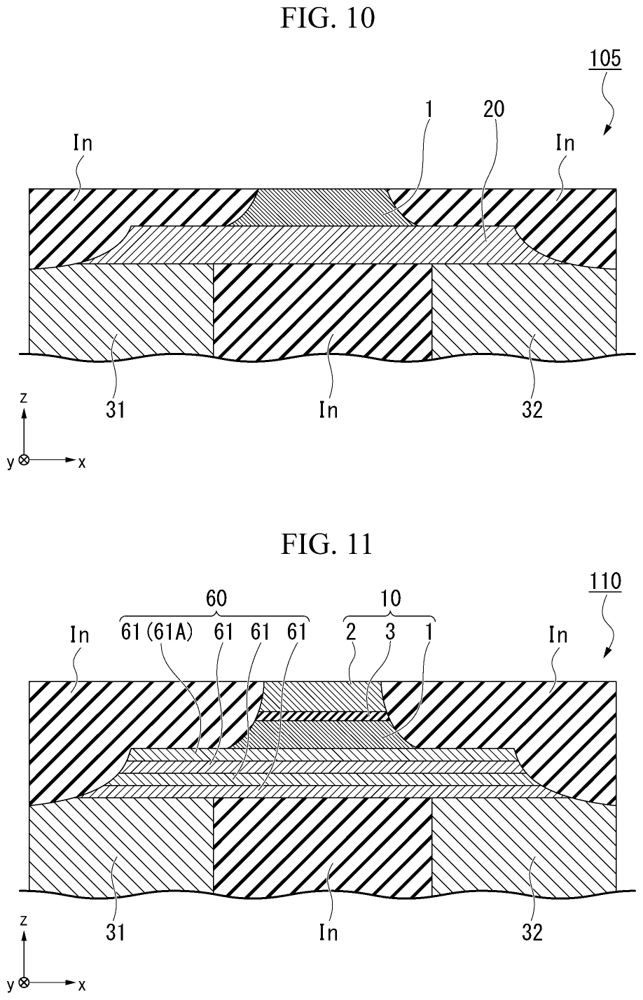

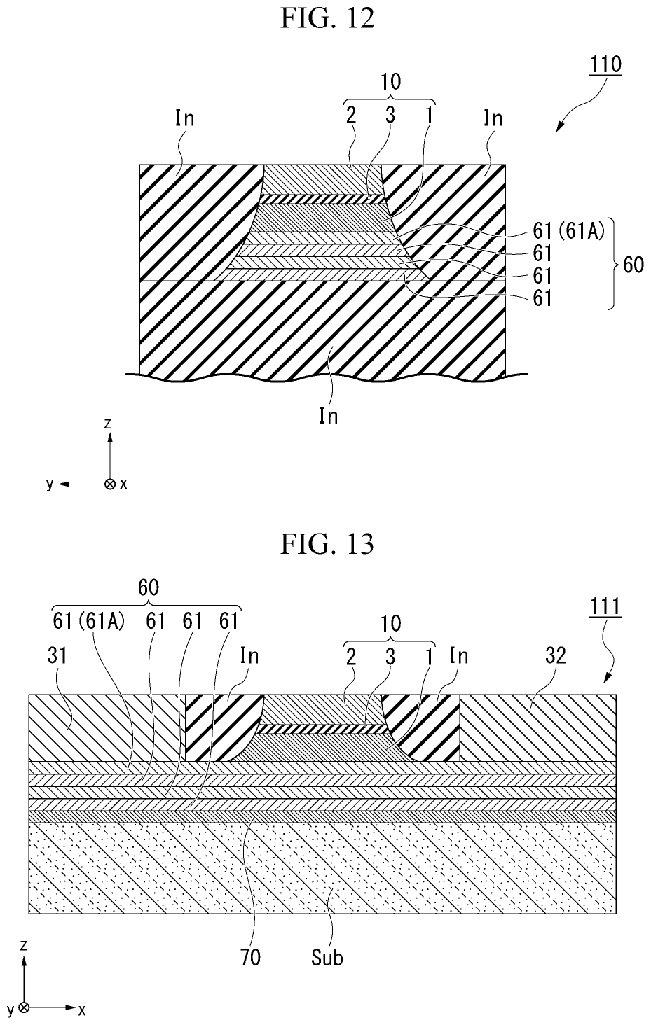

FIGS. 11 and 12 are cross-sectional views of a magnetoresistance effect element 110 according to a third embodiment. FIG. 11 is a cross section in a longitudinal direction of a spin-orbit torque wiring 60. FIG. 12 is a cross section along a surface orthogonal to the longitudinal direction of the spin-orbit torque wiring 60. The magnetoresistance effect element 110 can replace the magnetoresistance effect element 100 according to the first embodiment.

In the first embodiment and the second embodiment, since the spin-orbit torque wiring 20 has a pyrochlore structure, the amount of the write current required to reverse the magnetization of the first ferromagnetic layer 1 is reduced, and the power consumption of the entire magnetic memory 200 has been reduced. On the other hand, in the magnetoresistance effect element 110 according to the third embodiment, a stacked structure and a resistance of the spin-orbit torque wiring 60 are defined, and thus the power consumption of the entire magnetic memory 200 is reduced.

In the magnetoresistance effect element 110, the configuration of the spin-orbit torque wiring 60 is different from that of the spin-orbit torque wiring 20 of the magnetoresistance effect element 100. In the magnetoresistance effect element 110, the same constituent elements as those of the magnetoresistance effect element 100 are designated by the same reference signs, and the description thereof will be omitted.

The spin-orbit torque wiring 60 includes a plurality of wiring layers 61. The plurality of wiring layers 61 are stacked in the z direction. Each of the plurality of the wiring layers 61 generates a spin current due to a spin Hall effect when a current I flows and injects spins into the first ferromagnetic layer 1. The electrical resistivity of each of the plurality of wiring layers 61 is, for example, 1 mΩ·cm or more and preferably 10 mΩ·cm or less.

A product between a cross-sectional area and a resistivity of each wiring layer 61 is larger in the wiring layer 61 closer to the first ferromagnetic layer 1. That is, the wiring layer 61 closer to the first ferromagnetic layer 1 has a higher resistance. The resistance is determined by the resistivity specific to a material and the cross-sectional area which is the size of the flow path. The cross-sectional area is a cross-sectional area in a yz cross section shown in FIG. 12. The wiring layer 61 closest to the first ferromagnetic layer 1 among the plurality of wiring layers 61 is hereinafter referred to as a first wiring layer 61A. Among the wiring layers 61, the first wiring layer 61A has the largest product between the cross-sectional area and the resistivity.

The wiring layer 61 may contain, for example, one or more elements selected from the group consisting of Ag, Au, Mg, V, Pd, Cu, Si, and Al. Further, the wiring layer 61 may contain a heavy metal having an atomic number larger than that of yttrium. Further, the wiring layer 61 may contain a nitride. The nitride is, for example, a nitride of Ti, V, Cr, Zr, Nb, Mo, Ta, or W. The first wiring layer 61A may contain, for example, the above-mentioned compound having a pyrochlore structure.

When the resistance of the wiring layer 61 closer to the first ferromagnetic layer 1 is higher, it is possible to prevent part of the current flowing along the spin-orbit torque wiring 60 from being divided into the current toward the first ferromagnetic layer 1. In the first ferromagnetic layer 1, the spin flow is obstructed by the magnetization, and thus the spin Hall effect is less likely to occur. In other words, by reducing the write current that is divided into the write current toward the first ferromagnetic layer 1, it is possible to increase the amount of the write current flowing through the spin-orbit torque wiring 60, and it is possible to increase the spin current generated in the spin-orbit torque wiring 60. As a result, the amount of the spins injected into the first ferromagnetic layer 1 can be increased, the writing efficiency of the data can be increased, and the power consumption of the entire magnetic memory 200 can be reduced.

Further, when the spin-orbit torque wiring 60 includes the plurality of wiring layers 61, a plurality of interfaces are formed in the spin-orbit torque wiring 60. In the interface between different materials, a spin current is generated due to the Rashba effect. That is, the spin current is efficiently generated in the spin-orbit torque wiring 60, and the amount of the spins injected into the first ferromagnetic layer 1 is increased.

Although an example of the magnetoresistance effect element 110 according to the third embodiment has been shown above, addition, omission, replacement, and other changes in configuration can be made without departing from the spirit of the present invention.

For example, the characteristic configurations of the first modification example to the fourth modification example may be applied to the magnetoresistance effect element 110 according to the third embodiment. That is, the first intermediate layer 40 and/or the second intermediate layer 50 may be inserted between the spin-orbit torque wiring 60 and the stacked body 10. Further, the magnetoresistance effect element 110 may have a bottom pin structure. Further, similarly to the magnetization rotation element 105 according to the second embodiment, the nonmagnetic layer 3 and the second ferromagnetic layer 2 may be removed from the magnetoresistance effect element 110 to form the magnetization rotation element.

### FIFTH MODIFICATION EXAMPLE

Further, FIG. 13 is a cross-sectional view of a magnetoresistance effect element 111 according to a fifth modification example. The magnetoresistance effect element 111 has a spacer layer 70 on a side of the spin-orbit torque wiring 60 opposite to the first ferromagnetic layer 1. In the magnetoresistance effect element 111, the same constituent elements as those of the magnetoresistance effect element 110 are designated by the same reference signs, and the description thereof will be omitted.

The spacer layer 70 shown in FIG. 13 is located between the substrate Sub and the spin-orbit torque wiring 60. Depending on the material of the spin-orbit torque wiring 60, it may be difficult for crystals to grow on the substrate Sub. By using the spacer layer 70 as a base for the spin-orbit torque wiring 60, it is possible to enhance the crystallinity of the spin-orbit torque wiring 60, and it is possible to enhance the adhesion between the spin-orbit torque wiring 60 and the substrate Sub.

The spacer layer 70 contains, for example, any one or more elements selected from the group consisting of Cr, Ti, Ta, Ni, Ru, and W. The spacer layer 70 contains, for example, any one single metal layer selected from the group consisting of Ti, Ta, Ni, Ru, and W. The thickness of the spacer layer 70 is, for example, 3 nm or less.

The spacer layer 70 may be located at a location other than the location between the substrate Sub and the spin-orbit torque wiring 60. For example, in a case in which an insulating layer In is present between the substrate Sub and the spacer layer 70, the spacer layer 70 may be located between the insulating layer In and the spin-orbit torque wiring 60.

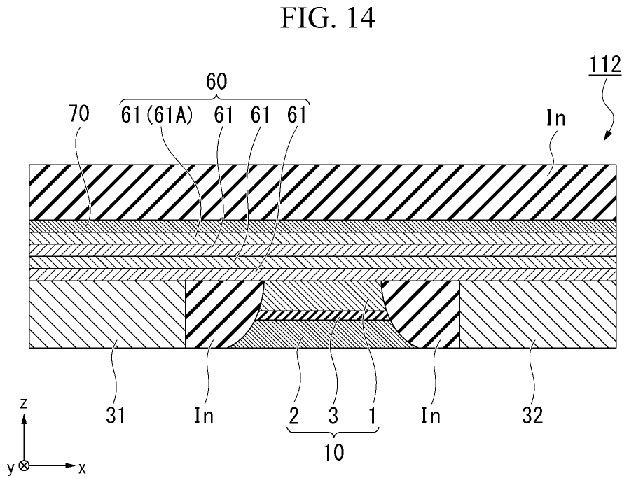

Further, as in the magnetoresistance effect element 112 shown in FIG. 14, the spacer layer 70 may be located above the spin-orbit torque wiring 60. The spacer layer 170 also functions as a stopper layer for etching. Further, in FIGS. 13 and 14, the spacer layer 70 is located on a side opposite to the first conductive layer 31 and the second conductive layer 32, but the first conductive layer 31 and the second conductive layer 32 may be connected to the spacer layer 70. The spacer layer 70 may be applied to the first embodiment and the second embodiment.

Although preferred aspects of the present invention have been described based on the first embodiment, the second embodiment, the third embodiment, and the modification examples above, the present invention is not limited to these embodiments. For example, the characteristic configurations in each embodiment and modification example may be applied to other embodiments and modification examples.

### EXPLANATION OF REFERENCES

1 First ferromagnetic layer

2 Second ferromagnetic layer

3 Nonmagnetic layer

10 Stacked body

20, 60 Spin-orbit torque wiring

31 First conductive layer

32 Second conductive layer

40 First intermediate layer

50 Second intermediate layer

61 Wiring layer

61A First wiring layer

70 Spacer layer

100, 101, 102, 103, 104, 110, 111, 112 Magnetoresistance effect element

105 Magnetization rotation element

200 Magnetic memory

CL Common wiring

RL Read wiring

WL Write wiring

In Insulating layer

1. A magnetization rotation element comprising:
a spin-orbit torque wiring; and
a first ferromagnetic layer which is stacked on the spin-orbit torque wiring,
wherein the spin-orbit torque wiring includes a plurality of wiring layers, and
wherein, in a cross section orthogonal to a length direction of the spin-orbit torque wiring, a product between a cross-sectional area and a resistivity of each of the wiring layers is larger in the wiring layer closer to the first ferromagnetic layer.

2. The magnetization rotation element according to claim 1, wherein the first wiring layer closest to the first ferromagnetic layer among the plurality of wiring layers contains a compound having a pyrochlore structure.

3. The magnetization rotation element according to claim 2, wherein the compound is an oxide.

4. The magnetization rotation element according to claim 3,
wherein the oxide is represented by a composition formula of R₂Ir₂O₇ in a stoichiometric composition, and
wherein R in the composition formula is at least one element selected from the group consisting of Pr, Nd, Sm, Eu, Gd, Tb, Dy, and Ho.

5. The magnetization rotation element according to claim 4,
wherein R in the composition formula includes a first element, and
wherein the first element is at least one of Pr and Nd.

6. The magnetization rotation element according to claim 4,
wherein R in the composition formula includes a first element and a second element,
wherein the first element is at least one of Pr and Nd, and
wherein the second element is at least one element selected from the group consisting of Sm, Eu, Gd, Tb, Dy, and Ho.

7. The magnetization rotation element according to claim 6, wherein a compositional proportion of the second element is smaller than a compositional proportion of the first element.

8. The magnetization rotation element according to claim 3, wherein the oxide is oxygen-deficient.

9. The magnetization rotation element according to claim 1, wherein the spin-orbit torque wiring has an electrical resistivity of 1 mΩ·cm or more.

10. The magnetization rotation element according to claim 1, wherein the spin-orbit torque wiring has an electrical resistivity of 10 mΩ·cm or less.

11. The magnetization rotation element according to claim 1, wherein any one of the plurality of wiring layers contains a heavy metal having an atomic number larger than that of yttrium.

12. The magnetization rotation element according to claim 1, wherein any one of the plurality of wiring layers contains one or more elements selected from the group consisting of Ag, Au, Mg, V, Pd, Cu, Si, and Al.

13. The magnetization rotation element according to claim 1, wherein any one of the plurality of wiring layers contains a nitride.

14. The magnetization rotation element according to claim 1, further comprising:
a spacer layer provided on an opposite side of the spin-orbit torque wiring from the first ferromagnetic layer,
wherein the spacer layer contains any one or more elements selected from the group consisting of Cr, Ti, Ta, Ni, Ru, and W.

15. The magnetization rotation element according to claim 14, wherein a film thickness of the spacer layer is 3 nm or less.

16. A magnetoresistance effect element comprising:
the magnetization rotation element according to claim 1;
a nonmagnetic layer in contact with the first ferromagnetic layer of the magnetization rotation element; and
a second ferromagnetic layer,
wherein the nonmagnetic layer is interposed between the first ferromagnetic layer and the second ferromagnetic layer.

17. A magnetic memory comprising:
a plurality of the magnetoresistance effect elements according to claim 16.

18. A method of manufacturing a spin-orbit torque wiring comprising:
a first film forming step of DC sputtering a metal at the same time as or after RF sputtering of an oxide to form an oxide layer having a pyrochlore structure.

19. The method of manufacturing a spin-orbit torque wiring according to claim 18,
wherein the oxide is R₂O₃ (R is at least one element selected from the group consisting of Pr, Nd, Sm, Eu, Gd, Tb, Dy, and Ho), and
wherein the metal is Ir.

20. The method of manufacturing a spin-orbit torque wiring according to claim 18, wherein the first film forming step is performed in an oxygen atmosphere.
